(19) United States
(12) Patent Application Publication
(10) Pub. No.: US 2024/0162509 A1
(43) Pub. Date: May 16, 2024

(54) SYSTEM FOR PLAUSIBILIZING A FIRST CLOCK OF A SYSTEM BASE CHIP OF AN ELECTROCHEMICAL ENERGY STORE AND METHOD FOR OPERATING A SYSTEM FOR PLAUSIBILIZING A FIRST CLOCK OF A SYSTEM BASE CHIP OF AN ELECTROCHEMICAL ENERGY STORE

(71) Applicant: Robert Bosch GmbH, Stuttgart (DE)

(72) Inventors: Jens Becker, Benningen Am Neckar (DE); Michael Besemer, Esslingen (DE)

(21) Appl. No.: 18/505,919

(22) Filed: Nov. 9, 2023

(30) Foreign Application Priority Data
Nov. 14, 2022 (DE) 10 2022 212 012.4

(51) Int. Cl. H01M 10/42; G01R 31/382; H01M 10/48

(52) U.S. Cl. CPC H01M 10/4285; G01R 31/382; H01M 10/48

(57) ABSTRACT

A system for plausibilizing a first clock of a system base chip of an electrochemical energy store that is turned on during an off state of the electrochemical energy store.

### BACKGROUND

The invention proceeds from a system for plausibilizing a first clock of a system base chip of an electrochemical energy store, a method for operating a system for plausibilizing a first clock of a system base chip of an electrochemical energy store, a computer program, and a use.

For high voltage (HV) and low voltage (LV) systems with, for example, lithium ion batteries, the battery's internal clock must be diagnosed during the off state of the battery. This is necessary for on-board diagnostic (OBD2) requirements regarding the state of health (SOH) determination and equalization processes for the battery's state of charge.

Two independent clocks are required for diagnosis. In the current state of the art, the system clock of the system base chip is used. This clock is switched on during the off state of the battery, all other clocks, for example from integrated circuits or microcontrollers, are disabled. The second independent clock is provided by the vehicle via the CAN bus that is used for evaluation. If there is a corresponding large deviation, an error signal is generated.

However, the clock provided by the vehicle does not have the necessary accuracy in all cases, thereby OBD2-compliant implementation of the diagnosis is not possible in these cases. The accuracy can lead to pseudo-errors, i.e., that the battery is incorrectly declared defective, for example due to a summer or winter time change, a replacement and reset as well as hardware errors of the external vehicle clock.

Document CN 211 015 875 U discloses a capture device having an accurate time synchronization function.

Document CN 104 410 400 A discloses a real-time clock synchronization circuit of a battery management system as well as an associated method.

Document CN 205 283 196 U discloses a clock supply circuit of a battery management system.

### SUMMARY

In contrast, the procedure according to the invention with the characterizing features of the disclosure has the advantage that the system for plausibilizing a first clock of a system base chip of an electrochemical energy store, which is switched on during an off state of the electrochemical energy store, comprises the following components:
a microcontroller having a second clock, which is switched off during the off state of the electrochemical energy store;
a cell measurement chip having a third clock, which may be operated during the off state of the electrochemical energy store, wherein the cell measurement chip periodically takes measurements using the third clock at a frequency predetermined by the microcontroller;
wherein, after the off state, an elapsed time duration since the start of the off state is calculated from a number of the measurements taken by the cell measurement chip and the frequency predetermined by the microcontroller, and the first clock is checked for plausibility using the predetermined time duration and the elapsed time duration.

Advantageously, with the system according to the invention, an external clock, for example a vehicle clock, can be dispensed with and an OBD2-compliant implementation can be ensured.

Advantageously, the microcontroller is woken up after a time duration predetermined by the first clock.

The second clock comprises a quartz oscillator as a clock and/or the third clock comprises a real-time clock.

A method according to the present invention for operating a system for plausibilizing a first clock of a system base chip of an electrochemical energy store comprises the following steps:
predetermining a frequency by a microcontroller having a second clock at which a cell measurement chip having a third clock is to periodically take measurements during an off state of the electrochemical energy store;
activating a sleep state of the microcontroller;
capturing a state variable representing an instantaneous state of the electrochemical energy store by the microcontroller;
comparing the actual state variables with target state variables which represent an end of the off state of the electrochemical energy stores;
capturing a number of measurements taken by the cell measurement chip by means of the microcontroller as a function of the comparison;
determining an elapsed time period since the start of the off state by means of the number of measurements taken and the predetermined frequency;
plausibilizing the first clock of the system base chip based on the predetermined time duration and the elapsed time duration;

Advantageously, the method according to the invention can also be used to generate information on the off-time of the electrochemical energy store, for example, which can be used for functional safety applications (FuSi, functions with ASIL quality), such as calculations of a charging state of the electrochemical energy store.

The method according to the invention for operating a system for plausibilizing a first clock of a system base chip of an electrochemical energy store further comprises the following step:
generating an error signal when a difference between a predetermined time duration and an elapsed time duration exceeds a predetermined threshold value.

The method according to the invention for operating a system for plausibilizing a first clock of a system base chip of an electrochemical energy store further comprises the following step:
plausibilizing the first clock by a second clock of a microcontroller outside the off state of the electrochemical energy store;

The device according to the invention for operating an electrochemical energy store comprising a system base chip having a first clock, a cell measurement chip having a third clock, and at least one means, in particular a microcontroller having a second clock, which are configured to perform the steps of the method according to the invention.

According to one advantageous embodiment of the invention, a computer program is provided, which comprises commands that cause the device for operating an electrochemical energy store to carry out the method steps according to the invention.

A machine-readable storage medium, on which the computer program is stored, is provided as well.

A system for plausibilizing a first clock of a system base chip according to the invention and/or a method for operating a system for plausibilizing a first clock of a system base chip according to the invention is advantageously used for electrochemical energy stores for electric vehicles, fuel cell vehicles, hybrid vehicles, plug-in hybrid vehicles, aircraft, pedelecs or e-bikes, for portable devices for telecommunications or data processing, for electric hand-held tools or food processors, and in stationary storage devices for storing in particular regeneratively produced electrical energy.

### BRIEF DESCRIPTION OF THE FIGURES

Exemplary embodiments of the invention are shown in the drawing and explained in more detail in the following description.

It shows:

FIG. 1 a schematic illustration of a system according to the invention for plausibilizing a first clock of an electrochemical energy store according to one embodiment; and

FIG. 2 a schematic illustration of a flowchart of an embodiment of a method according to the invention.

### DETAILED DESCRIPTION

Identical reference signs designate identical device components in all of the figures.

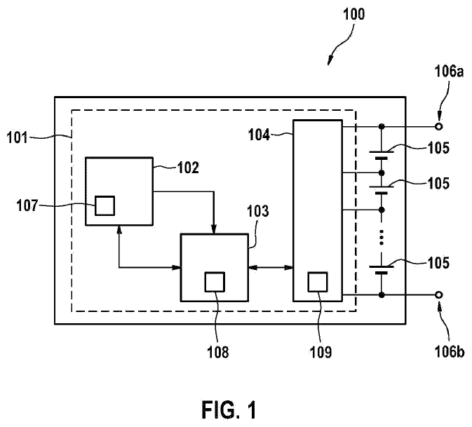

FIG. 1 a schematic illustration of a system 101 according to the invention for plausibilizing a first clock 107 of a system base chip 102, for example a CY327 or CY329, of an electrochemical energy store 100 according to one embodiment.

In addition to the system base chip 102 with the first clock 107, the system 101 according to the invention comprises a microcontroller 103 with a second clock 108 and a cell measurement chip 104 with a third clock 109.

The first clock 107 to be monitored is located in the system base chip 102 and serves to wake up the microcontroller 103 after a relaxation time has elapsed, i.e., an off state or a sleep phase of the electrochemical energy store 100. This first clock 107 must be monitored by the system 101 according to the present invention in order to meet corresponding OBD2 requirements.

In the embodiment shown, the second clock 108 of the microcontroller 103 is powered by quartz. A time measurement can be taken during operation using this clock. The microcontroller 103 is switched off during the relaxation time, so the second clock 108 is not suitable for monitoring the first clock 107 of the system base chip 102. Switching on the microcontroller 103 is not useful due to the comparatively high power consumption.

The cell measurement chip 104 is electrically connected to a plurality of electrochemical energy store cells 105 of the electrochemical energy store 100, for example to sense an electric voltage, current, and/or temperature of the electrochemical energy store cells 105.

Advantageously, the cell measurement chip 104 may be operated in a specific mode during the relaxation time, in which, for example, it takes measurements every 100 ms, 1,000 ms, or 10,000 ms. The measured values are discarded in the illustrated embodiment. The number of these measurements may be queried.

When the electrochemical energy store 100 is switched off, the cell measurement chip 104 operates in a specific mode, for example a 10 Hz mode, in which a measurement is taken every 100 ms. In the embodiment shown, the measured value is discarded. When the electrochemical energy store 100 wakes up, the number of measurements is read from a register of the cell measurement chip 104.

If a difference between the first clock 107 of the system base chip 102 and the number of measurements taken, divided by the predetermined frequency, deviates from a predetermined threshold value, then a failure of the first clock 107 can be reliably concluded.

The plausibility check of the first clock 107 advantageously has a “higher quality” compared to systems of the prior art and can also be used as ASIL information, for example for the charge state calculation of the electrochemical energy store cells 105 of the electrochemical energy store 100.

The electrochemical energy store cells 105 in the embodiment shown are electrically connected in series and electrically connected to poles 106a, 106b of the electrochemical energy store 100.

The system base chip 102, the microcontroller 103, and/or the cell measurement chip 104 are wired and/or wirelessly connected to each other. Further, the microcontroller 103 may be connected to another control unit, for example, an electrically driven vehicle, via a wired and/or wireless connection not shown.

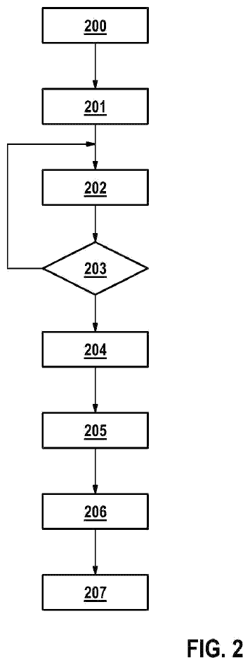

FIG. 2 shows a schematic illustration of a flow diagram of an embodiment of a method according to the invention for operating a system 101 for plausibilizing a first clock 107 of a system base chip 102 of an electrochemical energy store 100.

In step 200, a frequency is predetermined by the microcontroller 103 with the second clock 108 at which the cell measurement chip 104 is to periodically take measurements with a third clock 109 during an off state of the electrochemical energy store 100.

In step 201, an idle state of the microcontroller 103 is activated.

In step 202, a state variable is captured by the microcontroller 103, which represents an instantaneous state of the electrochemical energy store 100.

In step 203, the captured state variable is compared with a target state variable representing an end of the off state of the electrochemical energy store 100.

In step 204, a number of measurements taken by the cell measurement chip 104 is captured by the microcontroller 103 when the off state is ended. Otherwise, the method is continued in step 202.

In step 205, an elapsed time duration since the start of the off state is determined by means of the number of measurements performed and the predetermined frequency.

In step 206, the first clock 107 of the system base chip 102 is plausibilized based on the predetermined time duration and the elapsed time duration.

In step 207 an error signal is generated when a difference between a predetermined time duration and an elapsed time duration exceeds a predetermined threshold value.

1. A system (101) for plausibilizing a first clock (107) of a system base chip (102) of an electrochemical energy store (100) that is switched on during an off state of the electrochemical energy store (100), the system comprising:
a microcontroller (103) having a second clock (108) switched off during the off state of the electrochemical energy store (100);
a cell measurement chip (104) having a third clock (109) which can be operated during the off state of the electrochemical energy store (100), wherein the cell measurement chip (104) periodically takes measurements using the third clock (109) at a frequency predetermined by the microcontroller (103);
wherein, after ending the off state, an elapsed time duration since the start of the off state is calculated from a number of the measurements taken by the cell measurement chip (104) and the frequency predetermined by the microcontroller (103), and the first clock (107) is checked for plausibility using the predetermined time duration and the elapsed time duration.

2. The system (101) for plausibilizing a first clock (107) of a system base chip (102) of an electrochemical energy store (100) according to claim 1, wherein the microcontroller (103) is woken up after a time period predetermined by the first clock (107).

3. The system (101) for plausibilizing a first clock (107) of a system base chip (102) of an electrochemical energy store (100) according to claim 1, wherein the second clock (108) comprises a quartz oscillator as a clock generator and/or the third clock (109) comprises a real-time clock.

4. A method for operating a system (101) for plausibilizing a first clock (107) of a system base chip (102) of an electrochemical energy store (100), comprising the following steps:
(200) determining a frequency by a microcontroller (103) having a second clock (108), at which a cell measurement chip (104) having a third clock (109) is to periodically take measurements during an off state of the electrochemical energy store (100);
(201) activating an idle state of the microcontroller (103);
(202) capturing a state variable representing an instantaneous state of the electrochemical energy store (100) by the microcontroller (103);
(203) comparing the state variable with a target state variable representing an end of the off state of the electrochemical energy store (100);
(204) capturing a number of measurements taken by the cell measurement chip (104) by means of the microcontroller (103) as a function of the comparison;
(205) determining an elapsed time period since the start of the off state by means of the number of measurements taken and the predetermined frequency; and
(206) plausibilizing the first clock (107) of the system base chip (102) based on the predetermined time duration and the elapsed time duration.

5. The method for operating a system (101) for plausibilizing a first clock (107) of a system base chip (102) of an electrochemical energy store (100), according to claim 4, further comprising the following step:
(207) generating an error signal when a difference between a predetermined time duration and elapsed time duration exceeds a predetermined threshold value.

6. The method for operating a system (101) for plausibilizing a first clock (107) of a system base chip (102) of an electrochemical energy store (100) according to claim 4, further comprising the following step:
plausibilizing the first clock (107) by a second clock (108) of a microcontroller (103) outside the off state of the electrochemical energy store (100);

7. A device for operating an electrochemical energy store unit (100) comprising a system base chip (102) having a first clock (107), a cell measurement chip (104) having a third clock (109), and a microcontroller (103) having a second clock (108), which are configured to perform the steps of the method according to claim 4.

8. A non-transitory, machine-readable storage medium containing instructions that when executed by a computer cause the computer to plausibilize a first clock (107) of a system base chip (102) of an electrochemical energy store (100), by:
(200) determining a frequency by a microcontroller (103) having a second clock (108), at which a cell measurement chip (104) having a third clock (109) is to periodically take measurements during an off state of the electrochemical energy store (100);
(201) activating an idle state of the microcontroller (103);
(202) capturing a state variable representing an instantaneous state of the electrochemical energy store (100) by the microcontroller (103);
(203) comparing the state variable with a target state variable representing an end of the off state of the electrochemical energy store (100);
(204) capturing a number of measurements taken by the cell measurement chip (104) by means of the microcontroller (103) as a function of the comparison;
(205) determining an elapsed time period since the start of the off state by means of the number of measurements taken and the predetermined frequency; and
(206) plausibilizing the first clock (107) of the system base chip (102) based on the predetermined time duration and the elapsed time duration.
